(19) United States
(12) Patent Application Publication
(10) Pub. No.: US 2009/0167368 A1
(43) Pub. Date: Jul. 2, 2009

(54) PRE-DRIVER CIRCUIT HAVING A POST-BOOST CIRCUIT

(76) Inventors: Hong H. CHAN, Portland, OR (US); JEFFREY E. SMITH, Aloha, OR (US)

Correspondence Address: KED & ASSOCIATES, LLP;INTEL CORPORATION, P.O. BOX 221200, CHANTILLY, VA, 20153-1200, US

(21) Appl. No.: 11/965,333

(22) Filed: Dec. 27, 2007

(51) Int. Cl. H03K 3/00

(52) U.S. Cl. 327/108

(57) ABSTRACT

A pre-driver is provided that includes a pre-boost circuit and a post-boost circuit. The post-boost circuit may include a pulse generator circuit to provide a feedback to be used to control an output of the pre-driver.

### BACKGROUND

1. Field

Embodiments of the present invention may relate to a pre-driver.

2. Background

Boosters may be used in various different configurations to suit different applications. For example, pre-boost circuits and post-boost circuits may be used with input/output (I/O) buffers in digital input/output (I/O) buses. The boost circuits may improve bandwidth (switching frequency) of I/O buffers. However, an I/O driver (or driver) may use a pre-driver to control a slew rate and/or a Tco Rise/Fall skew.

### BRIEF DESCRIPTION OF THE DRAWINGS

Arrangements and embodiments may be described in detail with reference to the following drawings in which like reference numerals refer to like elements and wherein:

FIG. 1 is a schematic view of a pre-driver and a driver in accordance with an example arrangement;

FIG. 2 is a schematic view of a post-boost circuit of a pre-driver for both rising and falling edges in accordance with an example embodiment of the invention;

FIG. 3 is a schematic view of a pre-boost circuit of a pre-driver in accordance with an example embodiment of the present invention; and

FIG. 4 is a schematic view of a pre-driver having both a pre-boost circuit and a post-boost circuit in accordance with an example embodiment of the present invention.

### DETAILED DESCRIPTION

Embodiments of the present invention may include a pre-driver that includes a pre-boost circuit and a post-boost circuit. The post-boost circuit may use feedback of an output of the pre-driver for boost pulse generation.

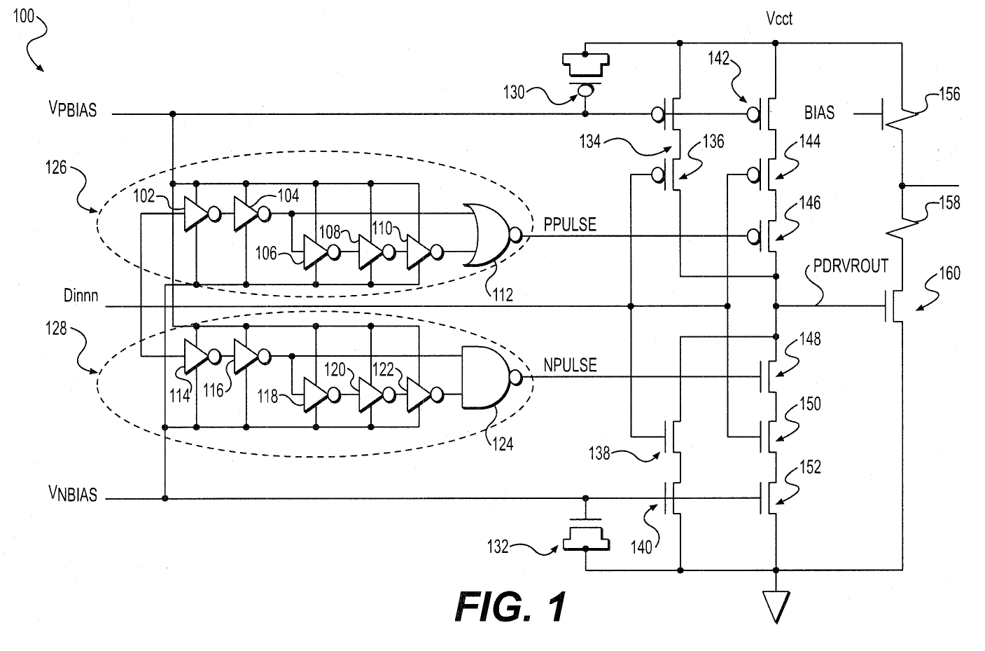

FIG. 1 is a schematic view of a pre-driver and a driver in accordance with an example arrangement. Other arrangements may also be used. More specifically, FIG. 1 shows a pre-driver 100 may include a pre-boost circuit, a post-boost circuit, a base driver (or a base driver circuit) and a boost circuit. The pre-driver 100 may include a first pulse generator circuit 126 and a second pulse generator circuit 128. The first pulse generator circuit 126 and the second pulse generator circuit 128 may output pulses to the boost circuit. The base driver may receive an input D_{INN} and include transistors 134, 136, 138 and 140. The boost circuit may include transistors 142, 144, 146, 148, 150 and 152. The driver circuit may include an on-die termination resistor 156 (or ODT), a resistor 158 and a transistor 160. The resistor 156 may be a combination of a p-channel metal oxide field effect transistor(s) and a resistor.

The transistors 130-152 and 160 may be field effect transistors (FETs) such as metal oxide field effect transistors (MOSFETs). For example, the transistors 130, 134, 136, 142, 144 and 146 may be a P-channel MOSFETs (or PMOS), and the transistors 132, 138, 140, 148, 150, 152 and 160 may be N-channel MOSFETs (or NMOSs).

As shown in FIG. 1, a positive bias voltage V_{PBIAS} may be applied to a gate of the transistor 130, to a gate of the transistor 134 and to a gate of the transistor 142. A source and a drain of the transistor 130 may be commonly coupled to a voltage supply Vcct.

A negative bias voltage V_{NBIAS} may be applied to a gate of the transistor 132, to a gate of the transistor 140 and to a gate of the transistor 152. A source and a drain of the transistor 132 may be commonly coupled to GROUND.

A source of the transistor 134 may be coupled to the voltage supply Vcct. A drain of the transistor 134 may be coupled to a source of the transistor 136.

An input D_{INNN} may be applied to a gate of the transistor 136 (of the base driver), to a gate of the transistor 144 (of the boost circuit), to a gate of the transistor 138 (of the base driver) and to a gate of the transistor 150 (of the boost circuit). A source of the transistor 136 may be coupled to the drain of the transistor 134. A drain of the transistor 136 may be coupled to a pre-driver output PDRVROUT of the pre-driver 100.

A drain of the transistor 138 may be coupled to a drain of the transistor 148. A source of the transistor 138 may be coupled to a drain of the transistor 140. A drain of the transistor 140 may be coupled to the source of the transistor 138. A source of the transistor 140 is coupled to the source of the transistor 160. A source of the transistor 142 may be coupled to the voltage supply Vcct. A drain of the transistor 142 may be coupled to a source of the transistor 144. A drain of the transistor 144 may be coupled to the source of the transistor 146.

The first pulse generator circuit 126 may include inverters 102, 104, 106, 108, 110 and a NOR gate 112 that performs a logical NOR operation (i.e., a not OR operation) based on inputs. The first pulse generator circuit 126 may generate a positive pulse PPULSE (or positive pulses) that is a control pulse for the boost circuit. The pulse PPULSE may be applied to a gate of the transistor 146. A source of the transistor 146 may be coupled to the drain of the transistor 144. A drain of the transistor 146 may be coupled to the drain of the transistor 136.

The second pulse generator circuit 128 may include inverters 114, 116, 118, 120, 122 and a NAND gate 124 that performs a logical NAND operation (i.e., a not AND operation) based on inputs. The second pulse generator circuit 128 may generate a negative pulse NPULSE (or negative pulses) that is a control pulse for the boost circuit. The pulse NPULSE may be applied to a gate of the transistor 148. A source of the transistor 148 may be coupled to a drain of the transistor 150. A drain of the transistor 148 may be coupled to the drain of the transistor 138.

A drain of the transistor 150 may be coupled to the source of the transistor 148 and a source of the transistor 150 may be coupled to a drain of the transistor 152. A drain of the transistor 152 may be coupled to the source of the transistor 150 and a source of the transistor 152 may be coupled to GROUND.

The on-die termination (ODT) resistor 156 may be coupled to the voltage supply Vcct and to the resistor 158. The on-die termination resistor 156 may receive a bias voltage BIAS. In order to reduce the resistance variations due to silicon fabrication Process, operation supply Voltage and Temperature (PVT), a MOS transistor may be used to implement the ODT resistor 156. Source to drain resistance of a transistor of the ODT resistor 156 may be set by a bias (i.e., the voltage at the transistor's gate). The bias voltage generator with a closed-loop feedback control may compensate the PVT variations. The closed-loop bias generator may provide bias to the transistor based on PVT in real time. To improve linearity, the structure of the ODT resistor 156 may be a combination of active devices (MOS transistors) and passive devices (resistors).

A drain of the transistor 160 may be coupled to the resistor 158 and a source of the transistor 160 may be coupled to GROUND. The pre-driver output PDRVROUT may be applied to the driver, namely to a gate of the transistor 160.

The pulses PPULSE and NPULSE may be control pulses to switch the transistors 146 and 148 (of the boost circuit) ON and OFF. The control pulses PPULSE and NPULSE may turn the boost circuit(s) ON and/or OFF during buffer switching. The pulse generator circuits 126, 128 may use the input D_{INN} of the pre-driver 100 to generate the control pulses (or delay pulses). However, a width of the pulses may vary significantly over process, voltage and temperature variations. The pulses may affect other functions of the pre-driver 100, such as I/O buffer slew rate and Tco Rise/Fall skew.

Process, voltage and temperature (PVT) are three variables that influence performance of solid state electronic circuits. More specifically, PVT variations may affect circuit performance, such as timing skew. For example, on a semiconductor die deviations in fabrication processes and/or variations in circuit operation may result in PVT variations of varying quantity across the die. These variations may produce local variations in circuit performance. Thus, the generation and propagation of data and control signals may differ even on a same integrated circuit die. For example, a circuit delay element located in one area of the die may provide a different amount of signal delay than another circuit delay element. As a result, PVT variations may directly impact signal communications.

Due to PVT variations, widths of the pulses PPULSE and NPULSE may vary. This may result in different shapes of the pre-driver output PDRVROUT and may lead to driver output edge rate, clock-to-out time (or Tco) Rise/Fall mismatch. These parameters may affect IO buffer performance.

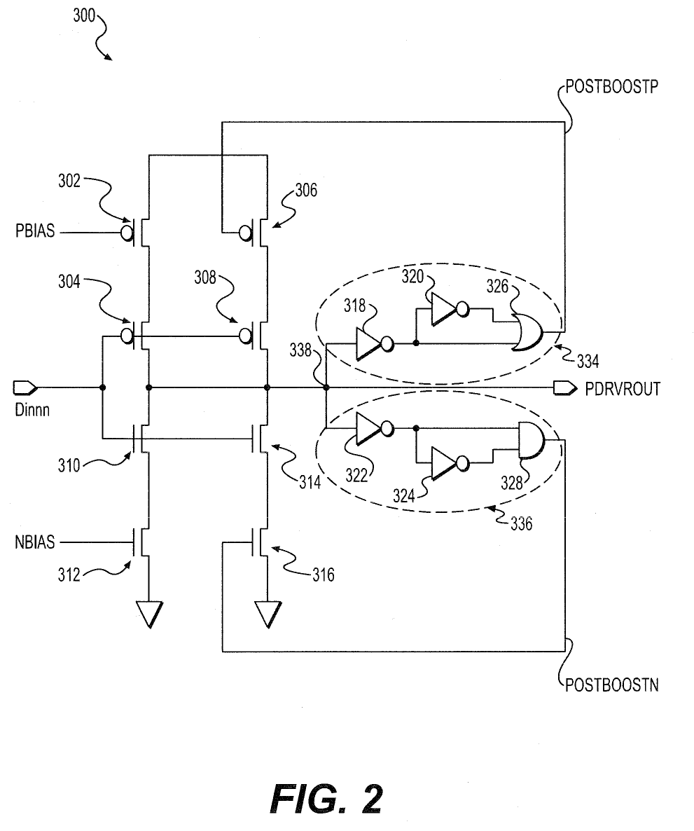

FIG. 2 is a schematic view of a post-boost circuit of a pre-driver for both rising and falling edges in accordance with an example embodiment of the present invention. Other embodiments and configurations are also within the scope of the present invention. FIG. 2 does not show the driver to receive the pre-driver output PDRVROUT. However, the pre-driver output PDRVROUT may be applied to a driver, such as to the transistor 160 shown in FIG. 1.

More specifically, FIG. 2 shows a base driver (or base driver circuit) and a post-boost circuit, which may collectively be referred to as a post-boost circuit 300. The post-boost circuit 300 may include transistors 302, 304, 306, 308, 310, 312, 314 and 316, inverters 318, 320, 322, 324, an OR gate 326, and an AND gate 328. The OR gate 326 performs a logical OR operation based on inputs. The AND gate 328 performs a logical AND operation based on inputs.

The post-boost circuit 300 may generate boost pulses by using the pre-driver output as feedback. This may make controlling pulse delay insignificant to the post-boost circuit 300, thereby leading to preservation of edge rate and Tco skew.

The post-boost circuit 300 may include a first pulse generator circuit 334 and a second pulse generator circuit 336. The first pulse generator circuit 334 may include the inverter 318, the inverter 320 and the OR gate 326 to form rising edges of a boost pulse.

The second pulse generator circuit 336 may include the inverter 322, the inverter 324 and the AND gate 328 to form falling edges of a boost pulse. The failing edge pulse generation is a dual process of rising edge pulse generation.

The transistors 302-316 may be field effect transistors (FETs) such as MOSFETs. For example, the transistors 302, 304, 306 and 308 may be P-channel MOSFETs (or PMOSs).

As shown in FIG. 2, a positive bias voltage PBIAS may be applied to the gate of the transistor 302 (of the base driver) and a negative bias voltage NBIAS may be applied to the gate of the transistor 312 (of the base driver).

The drain of the transistor 302 may be coupled to the source of the transistor 304 (of the base driver). The source of the transistor 302 may be coupled to the source of the transistor 306 (of the base driver).

The input D_{INNN} may be applied to the gate of the transistor 304 (of the base driver), to the gate of the transistor 310 (of the base driver), to the gate of the transistor 308 and to the gate of the transistor 314. The source of the transistor 304 may be coupled to the drain of the transistor 302. The drain of the transistor 304 may be coupled to the drain of the transistor 310.

The gate of the transistor 306 may be coupled to an output of the OR gate 326 to receive the feedback POSTBOOSTP. Stated differently, the output of the OR gate 326 of the first pulse generator circuit 334 may be input to the gate of the transistor 306. The source of the transistor 306 may be coupled to the source of the transistor 302 and the drain of the transistor 306 may be coupled to the source of the transistor 308.

The source of the transistor 308 may be coupled to the drain of the transistor 306, and the drain of the transistor 308 may be coupled to the drain of the transistor 314.

The transistors 310, 312, 314 and 316 may be N-channel MOSFETs (or NMOSs). The drain of the transistor 310 may be coupled to the drain of the transistor 304, and the source of the transistor 310 may be coupled to the drain of the transistor 312.

The negative bias voltage NBIAS may be applied to the gate of the transistor 312 (of the base driver). The drain of the transistor 312 may be coupled to the source of the transistor 310 (of the base driver), and the source of the transistor 312 may be coupled to GROUND.

The drain of the transistor 314 may be coupled to the drain of the transistor 308, and the source of the transistor 314 may be coupled to the drain of the transistor 316.

A gate of the transistor 316 may be coupled to an output of the AND gate 328 to receive the feedback POSTBOOSTN. Stated differently, the output of the AND gate 328 of the second pulse generator circuit 336 may be input to the gate of the transistor 316. The source of the transistor 316 may be coupled to GROUND, and the drain of the transistor 316 may be coupled to the source of the transistor 314.

The first pulse generator circuit 334 may also be referred to as a rising edge pulse generator that generates the feedback POSTBOOSTP. The second pulse generator circuit 336 may also be referred to as a falling edge pulse generator that generates the feedback POSTBOOSTN.

The term pulse generator may refer to pulse generators that allow control of pulse repetition rate (frequency), pulse width, delay with respect to internal or external trigger and high- and low-voltage levels of pulses. Pulse generators may allow control over rise time and fall time of pulses. Pulse generators may use digital techniques, analog techniques, or a combination of both techniques to form output pulses.

As shown in FIG. 2, an input of the inverter 318 may be coupled to a node 338, which corresponds to an output node of the post-boost circuit 300. The post-boost circuit 300 may provide the pre-driver output PDRVROUT to a driver circuit, such as the driver shown in FIG. 1. An output of the inverter 318 may be provided to an input of the inverter 320 and to one input of the OR gate 326. The inverter 320 may provide an output to another input of the OR gate 326. The OR gate 326 may perform a logical OR operation based on the inputs to the OR gate 326. The output of the OR gate 326 is the feedback POSTBOOSTP.

The feedback POSTBOOSTP is a boost pulse for the PMOS transistor 306. The arrival time of this pulse to the gate of the transistor 306 is a total delay of the inverter 318 and the OR gate 326. The pulse width is the delay of the inverter 320. This feedback POSTBOOSTP (or boost pulse) may provide an extra pull up to the pre-driver output PDRVROUT. This extra push of the pre-driver output PDRVROUT may result in an increasing switch bandwidth of the driver output. An arrival timing of the pulse to the post boost MOS device is on-time since the boost pulse may be generated by the pre-driver output PDRVROUT, and the rise time of the pre-driver output PDRVROUT may be much slower than the feedback pulse delay contributed by the transistor 318 and the OR gate 326. This may help ensure that the post boost happens in a second half of the switch transaction of the pre-driver output PDRVOUT. Using the feedback as a post boost pulse may result in meeting critical timing requirements for the post boost circuit.

The inverter 320 may act as a time delay element to set a pulse width of the boost pulse. The pulse width may not be critical as long as the pulse width covers the rise time of the pre-driver output PDRVROUT and is turned OFF prior to a rising edge of a next pre-driver output. The process, voltage and temperature (PVT) variations of the time delay may be negligible as compared to the rise time of the pre-driver output PDRVROUT. This may ease the PVT variations contributed by the delay element. As the result, the post-boost circuit 300 may not affect critical input/output (I/O) buffer parameters, such as the edge rate and the Tco skew.

An input of the inverter 322 may be coupled to the node 338, which corresponds to the output node of the post-boost circuit 300. An output of the inverter 322 may be provided as one input to the AND gate 328 and to an input of the inverter 324. The inverter 320 provides an output to another input of the AND gate 328. The AND gate 328 performs a logical AND operation based on the inputs to the AND gate 328. The output of the AND gate 328 is identified as feedback POSTBOOSTN. The feedback POSTBOOSTN is a dual process of the POSTBOOSTP. The feedback POSTBOOSTN is a boost pulse for the NMOS transistor 316. The arrival time of this pulse to the gate of the transistor 316 is a total delay of the inverter 322 and the NAND gate 328. The pulse width is the delay of the inverter 324.

The inverter 318, the OR gate 326 and the AND gate 328 may only perform logic functions. The time delay (or propagation delay) contributed by these logic gates may be very small.

The PVT variations of the time delay may be ignored as compared to the rise time of the pre-driver output. The inverter 320 may act as a time delay element to set the pulse width of the boost pulse. The pulse width (i.e., the boost circuit turn-on time) may not be critical as long as it covers the pre-driver output rise time and is turned OFF prior the next pre-driver rising edge. This may ease the PVT variations contributed by the delay element. As the result, this post-boost circuit may not affect critical input/output (I/O) buffer parameters (i.e., edge rate and Tco skew).

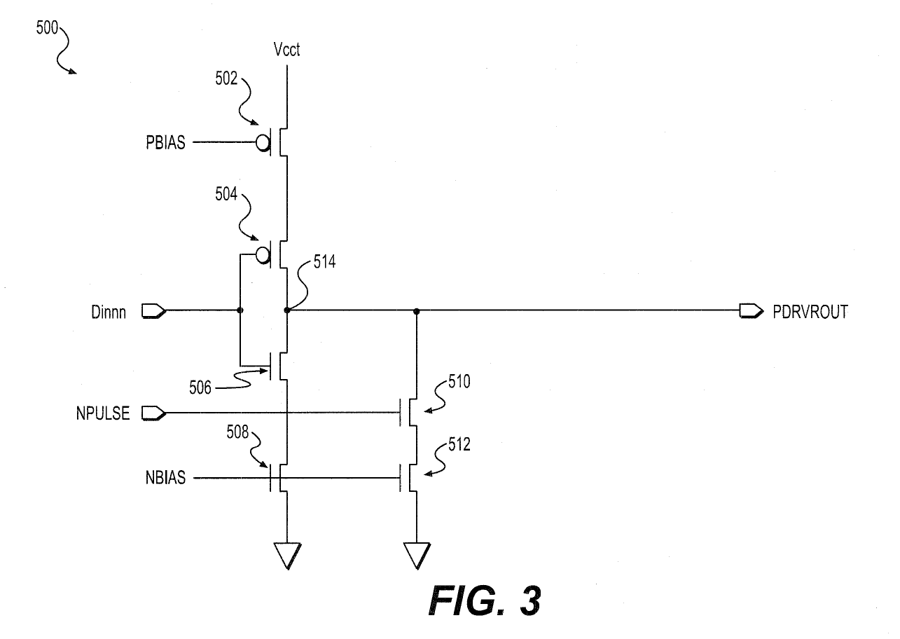

FIG. 3 is a schematic view of a pre-boost circuit of a pre-driver in accordance with an example embodiment of the present invention. Other embodiments and configurations are also within the scope of the present invention.

More specifically, FIG. 3 shows a pre-boost circuit 500 with pre-boost Tco adjustment. FIG. 3 does not show the driver to receive the pre-driver output PDRVROUT. However, the pre-driver output PDRVOUT may be applied to a driver, such as the transistor 160 shown in FIG. 1. The pre-boost circuit 500 may include transistors 502, 504, 506, 508, 510, and 512. The transistors 502 and 504 may be P-channel MOSFETs (or PMOSs), for example.

A positive bias voltage PBIAS may be applied to a gate of the transistor 502. A negative bias voltage NBIAS may be applied to a gate of the transistor 508. A source of the transistor 502 may be coupled to the voltage supply Vcct. A drain of the transistor 502 may be coupled to a source of the transistor 504.

The input D_{INNN} may be applied to a gate of the transistor 504 and to a gate of the transistor 506. A source of the transistor 504 may be coupled to the drain of the transistor 502, and a drain of the transistor 504 may be coupled through a node 514 to a drain of the transistor 506. A source of the transistor 506 may be coupled to a drain of the transistor 508.

The node 514 may provide the pre-driver output PDRVROUT, such as to a driver (not shown in FIG. 3).

A drain of the transistor 508 may be coupled to the source of the transistor 506 and a source of the transistor 508 may be coupled to GROUND.

A negative pulse signal NPULSE may be applied to a gate of the transistor 510. A drain of the transistor 510 may be coupled to an output node to provide the pre-driver output PDRVROUT. A source of the transistor 510 may be coupled to a drain of the transistor 512.

A negative bias voltage NBIAS may be applied to a gate of the transistor 512. A drain of the transistor 512 may be coupled to the source of the transistor 510, and a source of the transistor 512 may be coupled to GROUND.

The pre-boost circuit 500 shown in FIG. 3 does not have a boost circuit on a rising edge. However, the circuit 500 has a pre-boost circuit on a falling transaction, which also serves as Tco Rise/Fall alignment to improve Tco Rise/Fall skew.

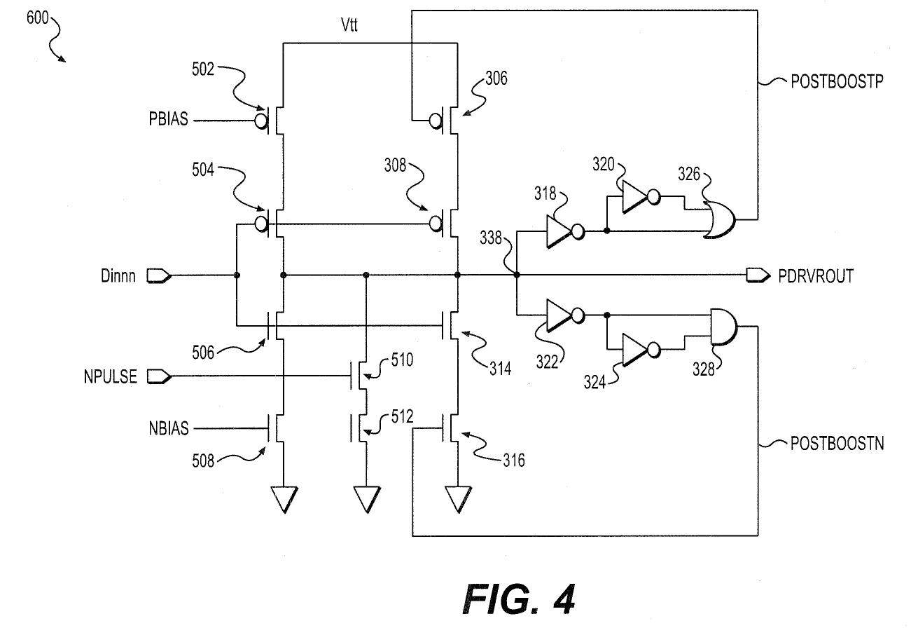

FIG. 4 is a schematic view of a pre-driver with both a pre-boost circuit and a post-boost circuit in accordance with an example embodiment of the present invention. Other embodiments and configurations are also within the scope of the present invention.

More specifically, FIG. 4 shows a pre-driver 600 that includes a pre-boost circuit (such as similar to the circuit 500 shown in FIG. 3) and a post-boost circuit (such as similar to portions of the circuit 300 shown in FIG. 2).

The transistor 306 may be a P-channel MOSFET (or PMOS). The feedback output POSTBOOSTP of the OR gate 326 may be applied to a gate of the transistor 306. A source of the transistor 306 may be coupled to the source of the transistor 502. A drain of the transistor 306 may be coupled to a source of the transistor 308.

The transistor 308 may be a P-channel MOSFET (or PMOS). The input D_{INNN} may be applied to a gate of the transistor 308. A source of the transistor 308 may be coupled to the drain of the transistor 306, and a drain of the transistor 308 may be coupled to the drain of the transistor 314. The n ode 338 may provide the output PDRVROUT.

The inverters 318 and 320 and the OR gate 326 may form a first pulse generator circuit as described above. More specifically, the output of the inverter 318 may be coupled to the input of the inverter 320 and to one input of the OR gate 326. The inverter 320 provides an output to another input of the OR gate 326. The OR gate 326 performs a logical OR operation based on the inputs of the OR gate 326. The first pulse generator circuit provides the feedback POSTBOOSTP, which is applied to a gate of the transistor 306 (of the boost circuit).

Additionally, the inverters 322 and 324 and the AND gate 328 may form a second pulse generator circuit as discussed above. More specifically, the output of the inverter 322 may be coupled to the input of the inverter 324 and to the input of the inverter 324. The inverter 322 provides an output to another input of the AND gate 328. The OR gate 328 performs a logical AND operation based on the inputs of the AND gate 326. The second pulse generator circuit provides the feedback POSTBOOSTN, which is applied to a gate of the transistor 316 (of the boost circuit)

A gate of the transistor 316 may be coupled to an output of the AND gate 328 to receive the feedback POSTBOOSTN. Stated differently, the output of the AND gate 328 of the second pulse generator circuit may be input to the gate of the transistor 316. The source of the transistor 316 may be coupled to GROUND, and the drain of the transistor 316 may be coupled to the source of the transistor 316.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A pre-driver comprising:
a first circuit to receive an input signal and to provide a pre-driver output on a pre-driver output node; and
a post-boost circuit to couple to the first circuit and to the pre-driver output node, the post-boost circuit including a plurality of transistors, a first pulse generator circuit to provide a first feedback signal as an input to one of the transistors and a second pulse generator circuit to provide a second feedback signal to another one of the transistors.

2. The pre-driver of claim 1, wherein the first feedback signal to provide a boost pulse to the one transistor.

3. The pre-driver of claim 1, wherein the first pulse generator circuit comprises a rising edge pulse generator.

4. The pre-driver of claim 1, wherein the first pulse generator circuit comprises at least one inverter and an OR gate.

5. (canceled)

6. The pre-driver of claim 1, wherein the second pulse generator circuit comprises at least one inverter and an AND gate.

7. The pre-driver of claim 1, wherein the first circuit comprises a base driver circuit or a pre-boost circuit having a plurality of transistors.

8. A pre-driver comprising:
a pre-boost circuit to couple to an input node; and
a post-boost circuit to couple to an output node, the post-boost circuit including at least one transistor, a first pulse generator circuit to provide a first feedback signal to the at least one transistor to control a pre-driver output at the output node and a second pulse generator circuit to provide a second feedback signal to further control the pre-driver output at the output node.

9. The pre-driver of claim 8, wherein the first feedback signal to provide a boost pulse.

10-12. (canceled)

13. The pre-driver of claim 8, wherein the second feedback signal is to be applied to another transistor.

14. The pre-driver of claim 18, wherein the second pulse generator circuit comprises a falling edge generator circuit.

15. The pre-driver of claim 8, wherein the first pulse generator circuit comprises a rising edge pulse generator.

16. A pre-driver comprising:
a pre-boost circuit to couple to an input node; and
a post-boost circuit to couple to an output node, the post-boost circuit including a plurality of transistors, a first pulse generator circuit to provide a first feedback signal to a first one of the transistors and a second pulse generator circuit to provide a second feedback signal to a second one of the transistors, and the first feedback signal and the second feedback signal to control a pre-driver output at the output node.

17. The pre-driver of claim 16, wherein the first feedback signal to provide a boost pulse.

18. The pre-driver of claim 16, wherein the first pulse generator circuit comprises a rising edge pulse generator.

19. The pre-driver of claim 16, wherein the second pulse generator circuit comprises a falling edge generator circuit.
